(19) United States
(12) Patent Application Publication
(10) Pub. No.: US 2012/0261539 A1
(43) Pub. Date: Oct. 18, 2012

(54) Cushion pad apparatus

(76) Inventor: Pei-Lin HUANG, New Taipei City (TW)

(21) Appl. No.: 13/450,147

(22) Filed: Apr. 18, 2012

(30) Foreign Application Priority Data
Apr. 18, 2011 (TW) 100206803

(51) Int. Cl. H05K 7/20; H05K 7/00

(52) U.S. Cl. 248/346.03

(57) ABSTRACT

A cushion pad apparatus according to the present invention comprises a cushion pad having at least a receiving surface and a bottom surface; and an insertion frame selectively is contoured on said receiving surface. The insertion frame has an insertion well, and the insertion frame is disposed at a prescribed angle from said bottom surface, where adjustment of the prescribed angle operates to subject the insertion frame to move into an inclined position. A flat panel electronic device, upon disposition within the insertion frame, is supported at the prescribed angle accordingly as a structural consequence of the insertion well, while benefiting a user with subjecting the flat panel to face a user in a more direct, face-to-face fashion.

The current application claims a foreign priority to the patent application of Taiwan No. 100206803 filed on Apr. 18, 2011.

### BACKGROUND OF THE INVENTION

1. Field of the Invention

The present invention generally relates to a cushion pad apparatus for insertion of a flat panel electronic device. The to present invention specifically relates to a cushion pad for positioning a flat panel electronic device in a prescribed orientation, while also providing a pad for repose.

2. Description of the Prior Art

The present demand for cushion pad is well-received in various locations varying from household to business settings for its effect on increasing comfortability and reducing fatigue of users, such as, in business office or residential environment engaging in tv-watching, book-reading, or other leisure activities. It is generally known as a tool for posture support and also cushion for head protection, as a replacement for regular pillows.

Even though it is well known to the general public that addition of a cushion pad can significantly improve comfortability of its user during the user's sitting or sleep posture, the conventional arts reveal that they remain mostly for use as a support component only. The present invention has been made in view of improving the current state of art regarding cushion pad, thereby broading the scope of its applicability.

Accordingly, prospect for improvement is foreseeable in the related arts of cushion pad.

### SUMMARY OF THE INVENTION

It is an object of the present invention to provide a cushion pad apparatus for orienting a flat panel electronic device, the cushion pad apparatus can allow insertion of a flat panel electronic device, thereby enabling the apparatus to operate in a repose-supporting manner and a protective manner with regard to a flat panel electronic device.

It is also another object of the present invention to provide a cushion pad apparatus for orienting a flat panel electronic device such that the flat panel electronic device is subject to structural support of an insertion well, making the electronic device move into an inclined position for benefiting users ease of operation when the electronic device is placed into the cushion pad.

It is yet another object of the present invention to provide a cushion pad apparatus for orienting a flat panel electronic device where the cushion pad apparatus has a fastener, serving to prevent displacement of the electronic device from its inserted position from the insertion frame.

In a accordance with a general aspect of the present invention, the above and other objects can be attained by the provision of a cushion pad apparatus comprising a cushion pad having at least a receiving surface and a bottom surface, and an insertion frame selectively contoured on said receiving surface, wherein said insertion frame has an insertion well, and said insertion frame is disposed at a prescribed angle from said bottom surface.

In a preferred embodiment, the cushion pad apparatus has an exterior jacket covering an exterior surface of said cushion to pad.

In another preferred embodiment, the cushion pad apparatus has a fastener disposed over a portion of said insertion frame, wherein the fastener is a velcro hook-and-loose stripe or a guiding apparatus.

In yet another preferred embodiment, the cushion pad apparatus comprises a material selected from a porous material and silica gel.

In another preferred embodiment, cushion pad apparatus has the prescribed angle structured to be between at about 0 degree through 90 degrees In yet another preferred embodiment, the cushion pad apparatus further comprises at least a placer for installation of the flat panel electronic device for easy access and installation of a flat panel electronic device.

### BRIEF DESCRIPTION OF THE DRAWINGS

FIG. 1 depicts a cushion pad apparatus according to a first embodiment of the present invention.

FIGS. 2A-B are diagrams illustrating how a flat panel electronic device is inserted into, removed from a cushion pad apparatus according to the present invention.

FIG. 3 is a diagram illustrating how a cushion pad apparatus is used in a fashion according to the present invention.

FIG. 4 depicts a cushion pad apparatus according to a second to embodiment of the present invention.

FIGS. 5A-5C are perspective views illustrating various uses of a cushion pad apparatus in response to different user's posture.

FIG. 6 depicts a cushion pad apparatus according to a third embodiment of the present invention.

FIG. 7 depicts, in a cross-sectional perspective, a cushion pad apparatus according to a third embodiment of the present invention.

FIGS. 8A-B depict a cushion pad apparatus according to a fourth embodiment of the present invention.

FIG. 9 is a diagram illustrating operation of the cushion pad apparatus as appeared in FIGS. 8A-8B.

FIGS. 10A-10B depict a cushion pad apparatus according to a fifth embodiment of the present invention.

FIG. 11 depicts a cushion pad apparatus according to a sixth embodiment of the present invention.

FIGS. 12A-12B depicts a cushion pad apparatus according to a seventh embodiment of the present invention.

### DETAILED DESCRIPTION OF THE INVENTION

Hereinafter, embodiments of the present invention will be described with reference to the figures. The embodiments which to are described here are merely examples, and the present invention is not necessarily restricted thereto.

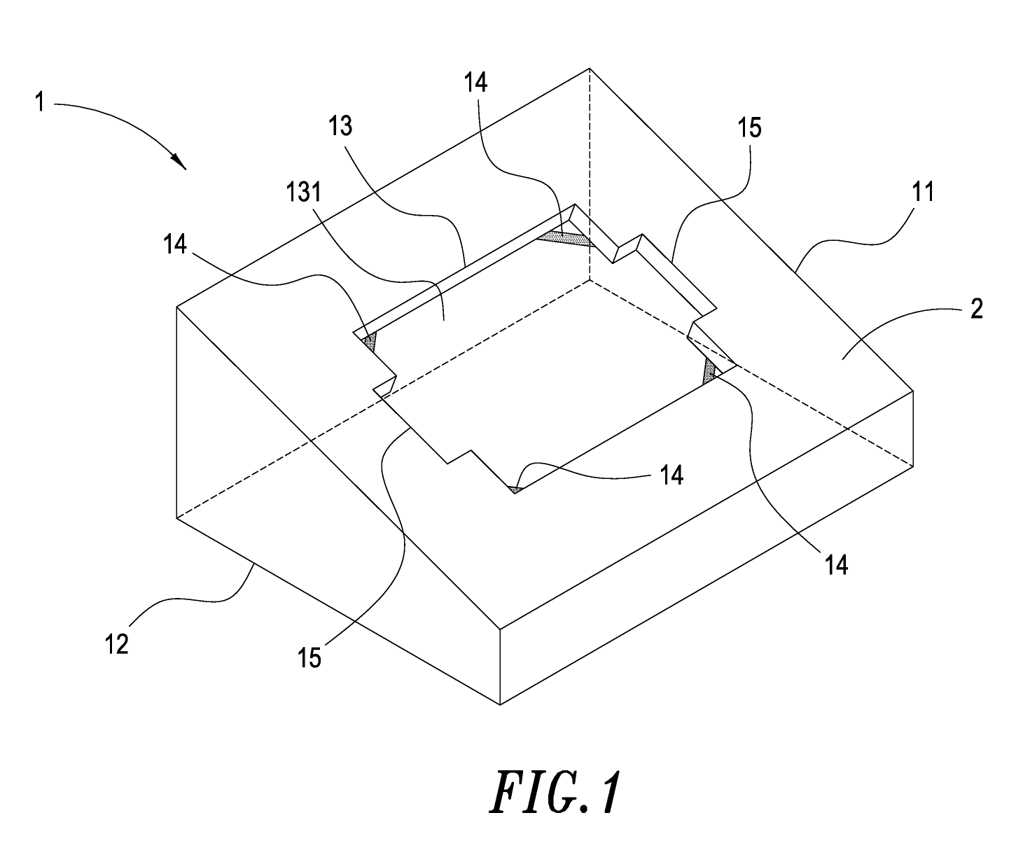

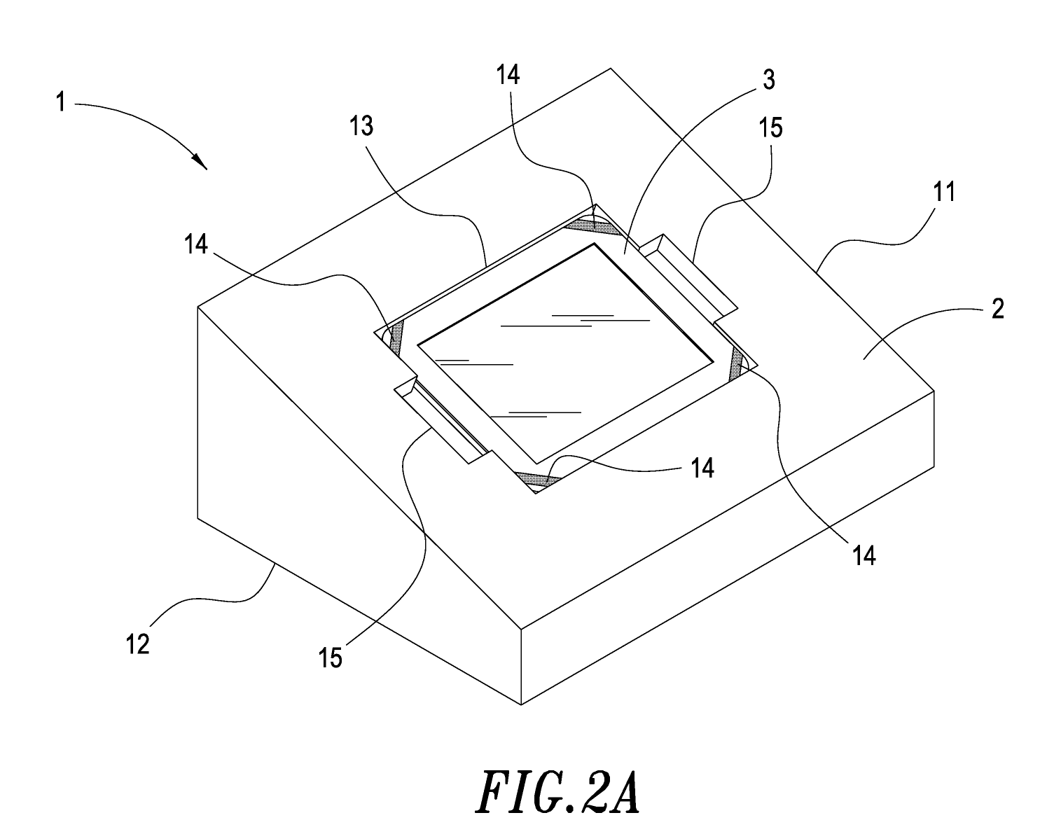

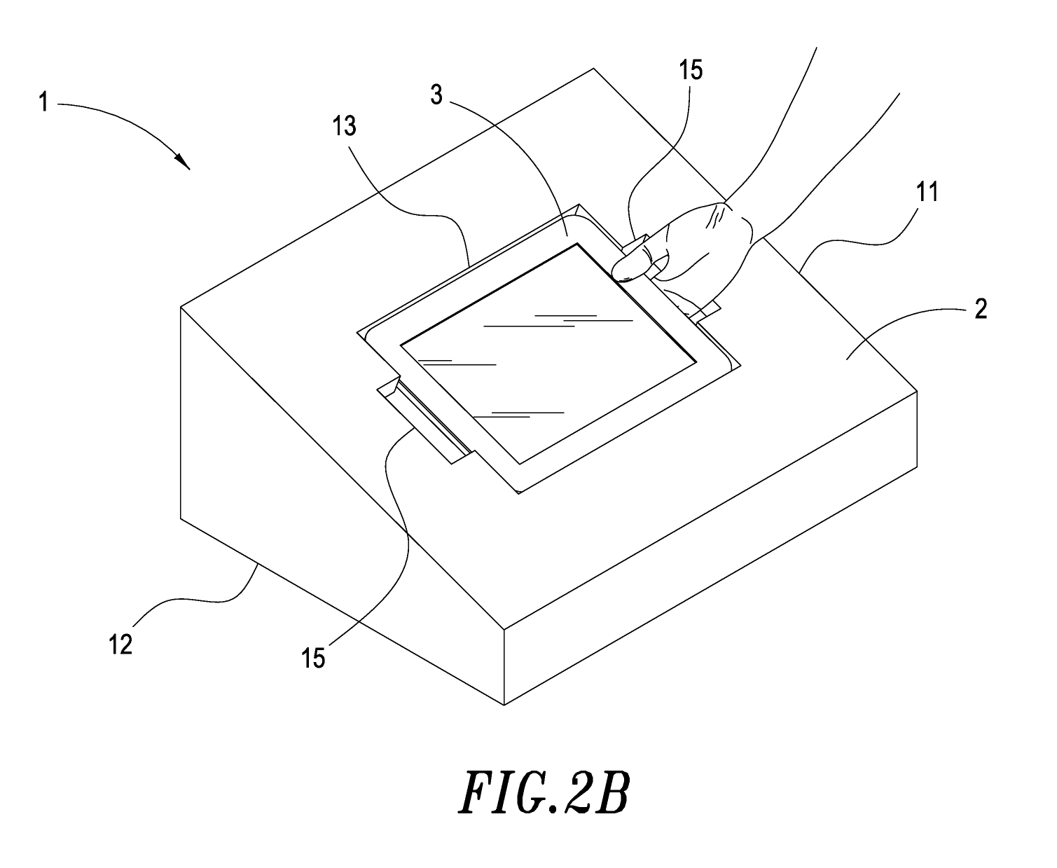

Referring to FIG. 1 and FIGS. 2A-2B, a first preferred embodiment of the prevent invention is shown. The cushion pad apparatus for insertion of a flat panel electronic device comprises a cushion pad 1, wherein the cushion pad 1 has at least a receiving surface 11 and a bottom surface 12, each of the receiving surface 11 and the bottom surface 12 corresponds to each other, and an insertion frame 13 is selectively contoured on the receiving surface 11, wherein the insertion frame 13 has an insertion well 131, and said insertion frame 131 is disposed at a prescribed angle from said bottom surface 12, which is so as to provide a viewing angle for viewing and operating a flat panel electronic device. Furthermore, an exterior jacket 2 covering an exterior surface of said cushion pad 1 is provided so as to protect the cushion pad 1 from damage, also a fastener 14 is disposed over a portion of an insertion well 131 and a surface of the insertion frame 13, the fastener 14 can be a guiding apparatus, thereby fixing the flat panel electronic device 3 in its original position and preventing said flat panel electronic device 3 from fall out. In addition, at least a placer 15 is installed on a side surface of the insertion frame 13.

Next, the flat panel electronic device 3 is disposed inside an insertion frame 13 of a cushion pad 1, supported by an insertion well 13 and can be fastener fixed in position with the insertion frame 13 or the fastener 14 on a wall surface thereof, as shown in FIG. 2A, thereby preventing the cushion pad 1 from going out of the insertion frame 13. Meanwhile, the cushion pad 1 is made of porous material to preserve the integrity of the flat panel electronic device 3 in the event that the cushion pad 1 is dropped offhand. The user may detach the fastener 14 and lift the cushion pad 1 with his or her fingers off from the placer 15 if he or she wishes to detach the flat panel electronic device 3 (as FIG. 2B discloses), therefore it is made easier to access the flat panel electronic device 3 so as to position it in a time-efficient manner.

In another perspective of the invention, the cushion pad 1 comprises porour material or silicon gel or exterior jacket fillings.

In yet another perspective of the invention, the prescribed angle delineated between the bottom surface 12 of the cushion 1 and the insertion frame 13 is between at about 0 degree through 90 degrees.

In another perspective of the invention, the guiding apparatus of the fastener 14 can be manufactured to have an elastic characteristics alike a highly extendable plastic belt.

In yet another perspective of the invention, the receiving surface 11 can be an inclined surface or a planar surface or an irregular surface.

In another perspective of the invention, the bottom surface can be an inclined surface of a planar surface or an irregular surface.

In yet another perspective of the invention, the exterior dimension of the insertion frame 13 can be modicumly smaller than that of the flat panel electronic device 3 if the cushion pad 1 is made from a buffering or elastic material so as to allow tight connection between the flat panel electronic device 3 and the insertion frame 13 of the cushion pad 1. At the same time, this is believed to be effective in preventing fall out from the insertion frame 13.

In another perspective of the invention, the placer 15 is disposed over two opposite ends of the insertion frame 13.

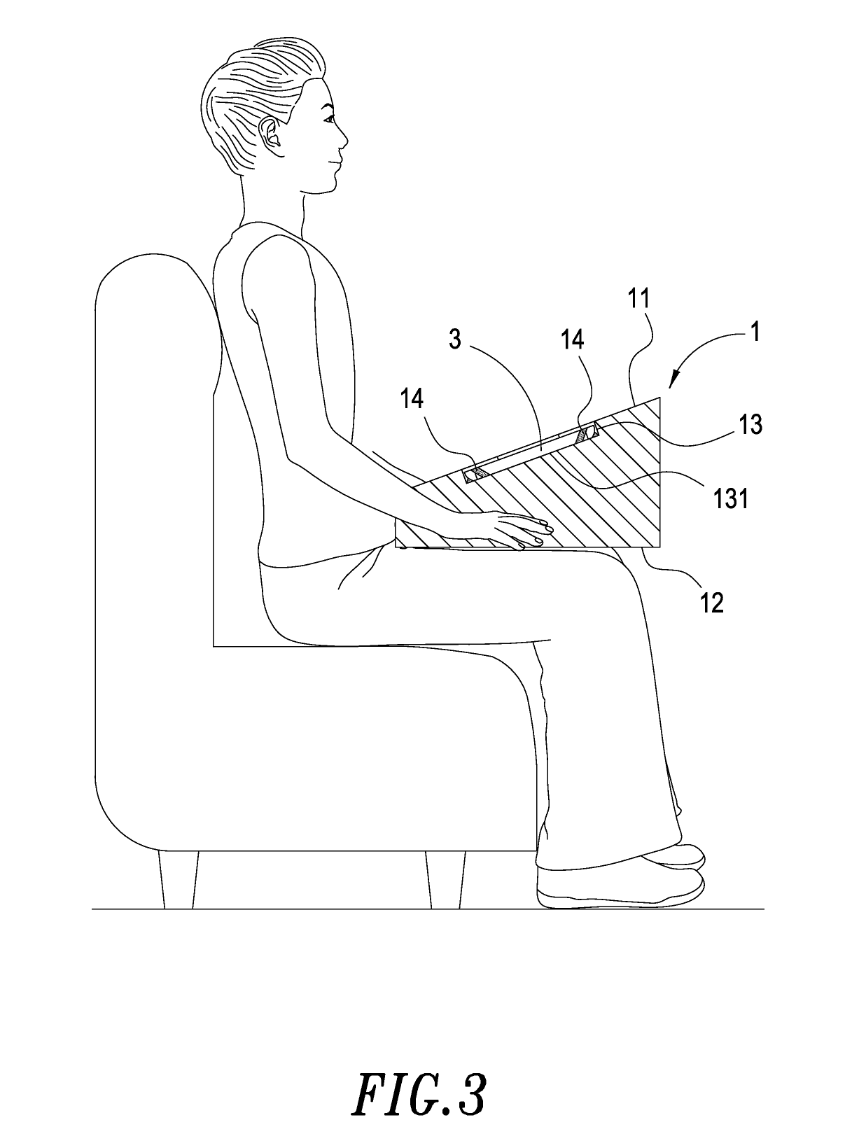

Referring now to FIG. 3, which is a diagram illustrating how a cushion pad apparatus is used in a fashion according to the present invention, the flat panel electronic device 3 is placed inside the insertion frame 13 of the cushion pad 1, and is supported by the insertion well 131 therein. Consequently the user can elect to place the cushion pad 1 on his or her thigh or a flat surface or an inclined surface as a supporting stand when using the electronic device. Meanwhile, the user can place his or her hand(s) on the receiving surface 11 of the cushion pad 1 during operation, and adjust accordingly the angle between the bottom surface 12 of the cushion pad 1 and insertion frame 13 to form an optimal viewing angle for reading or exercise of the flat panel electronic device 3. Furthermore, the cushion pad 1 is made from a porous material to allow a certain level of comfortability to the user when his or her hand(s) is placed thereupon.

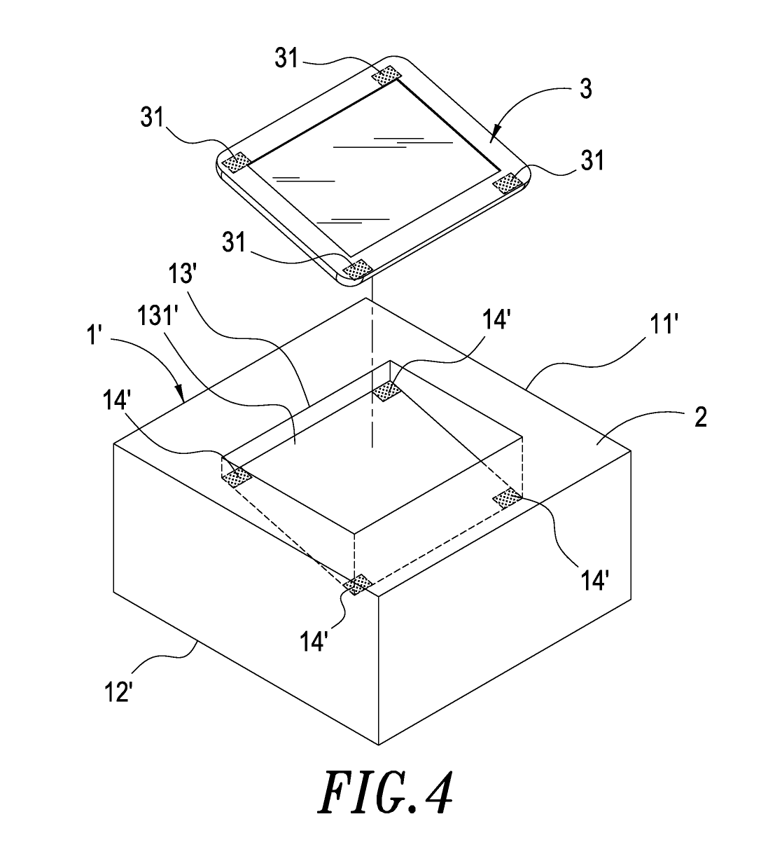

Turning now to FIG. 4, being a second embodiment of the present invention, the cushion pad 1 can be manufactured into different forms. Taking a cubic cushion pad 1′ as an example, an formed angle is required between the bottom surface 12′ of the to cushion pad 1′ and the insertion well 131′ of the insertion frame 13′ to form a viewing angle, with an exterior jacket 2 covering the cushion pad 1′. Furthermore, the insertion well 131′ may use a fastener made from velcro hook-and-lose stripe 14′, and the bottom surface of the flat panel electronic device 3 can be designed to have a corresponding velcro hook-and-loose stripe 31, making the connection more attached. Accordingly, an embodiment capable to be configured into a angle formation with the interaction between a bottom surface 12 of the cushion pad 1 and an insertion well 131′ in an insertion frame 13′ is within the breadth of patent protection of incumbent invention.

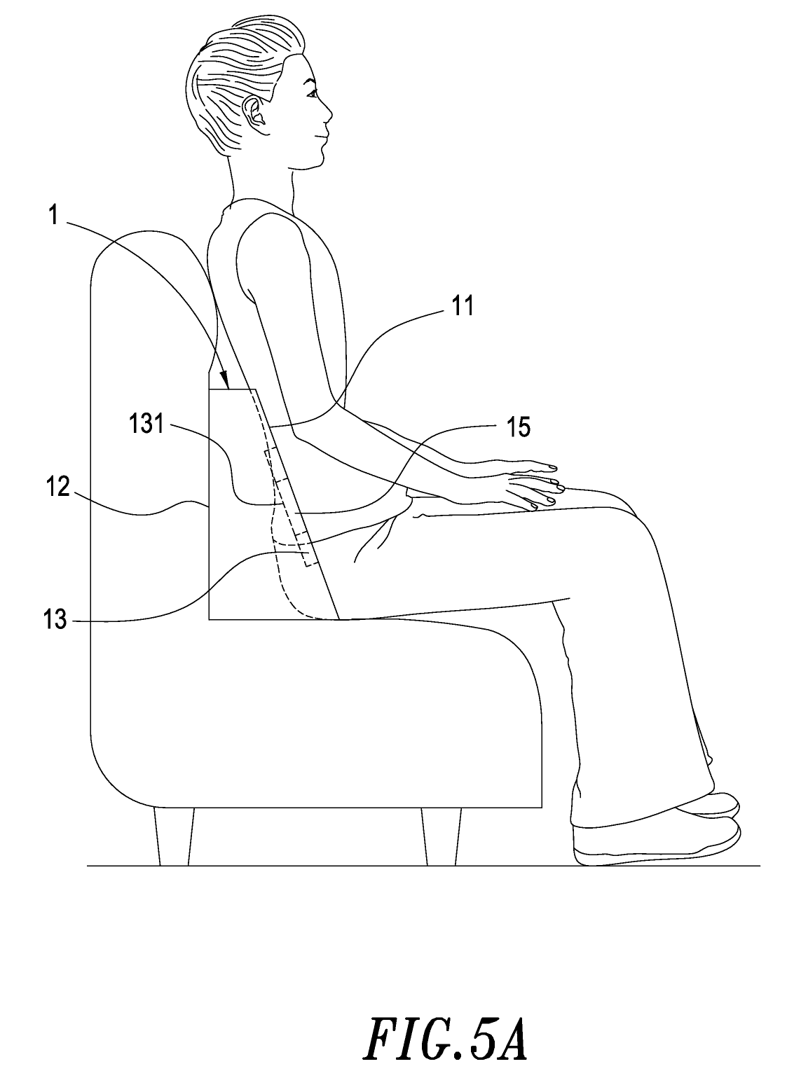

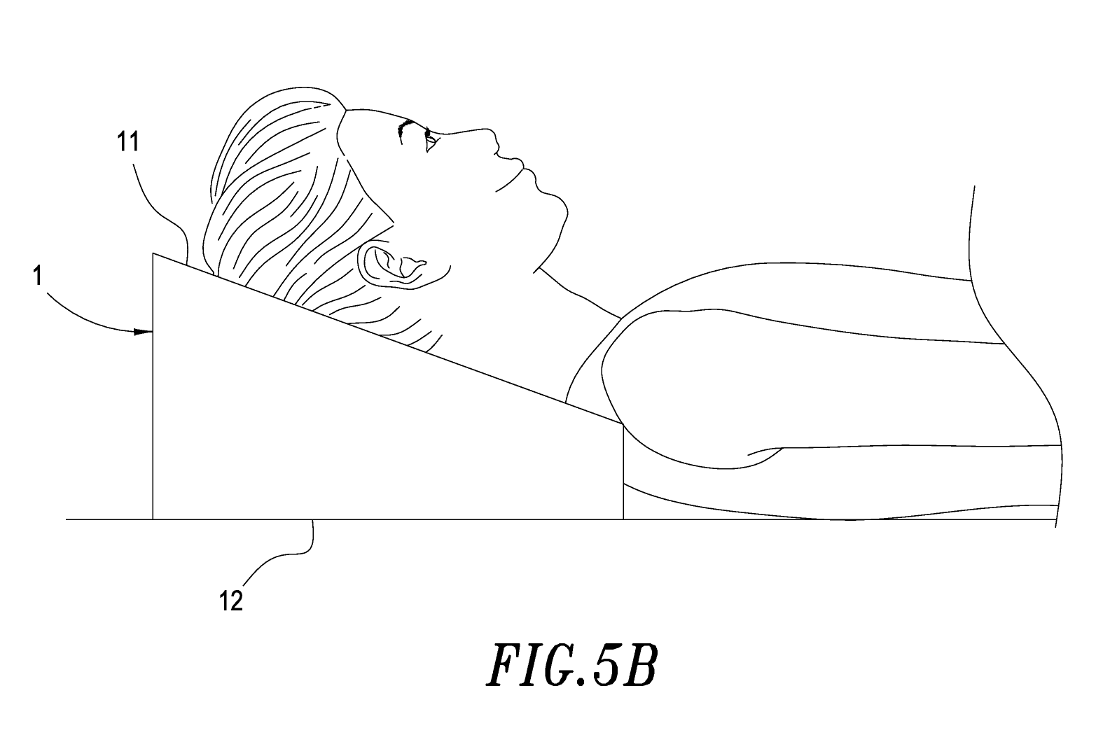

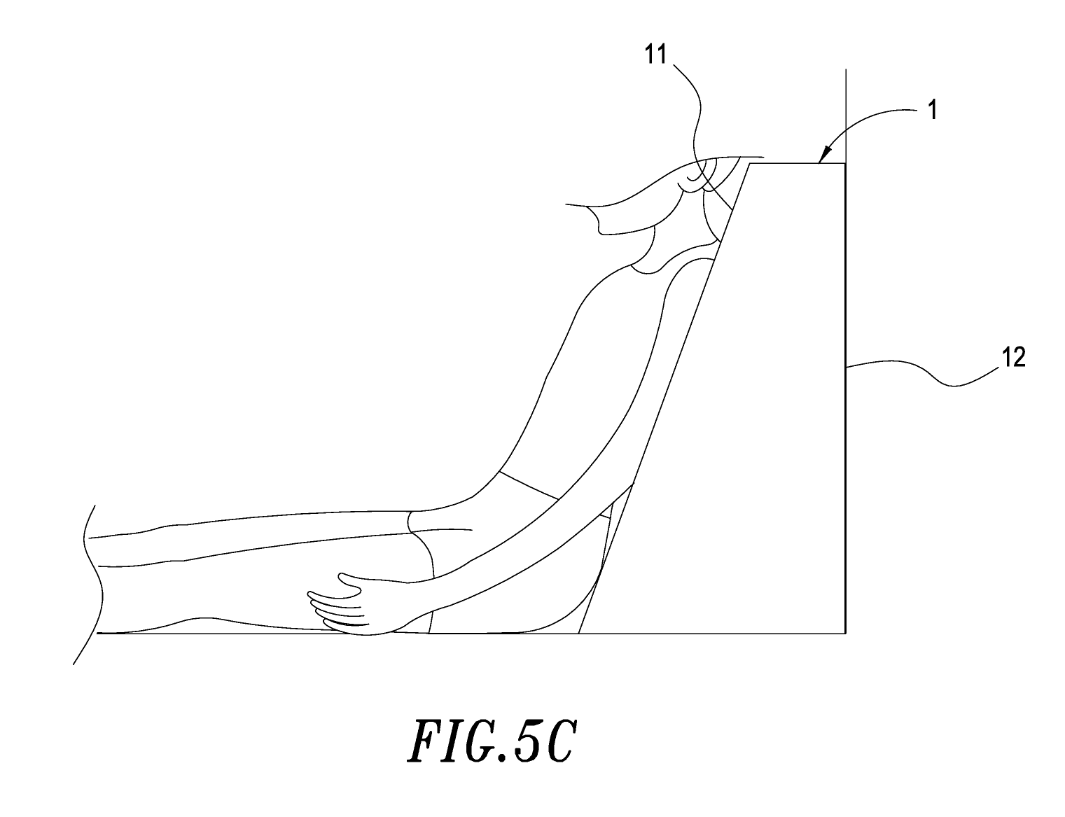

Next, turning to FIGS. 5A, 5B, and 5C, perspective views illustrating various uses of a cushion pad apparatus in response to different user's posture are presented. When the cushion pad 1 of the present invention is not cooperating with the flat panel electronic device 3, it is known to treat the invention as a conventional back-lying cushion pad, head-resting cushion pad or any large area cushion pad. As disclosed by FIG. 5A, cushion pad 1 is disposed on a seat so as to provide a receiving surface 11 as a supporting tool for user's waist. Otherwise, as disclosed by FIG. 5B, the cushion pad 1 is disposed on a bed surface, allowing the receiving surface 1 of the cushion pad to support the head and neck of the user, also, the insertion frame 13 can be used to fix the user'head in a specific position. The placer 15 can be treated as a resting region for user's ear(s) when the user is sleeping on his or her side, thereby improving the sleep quality. Otherwise, as disclosed by FIG. 5C, cushion pad 1 is disposed on the floor surface, to the bottom surface can allow user's waist, back, neck and head for resting.

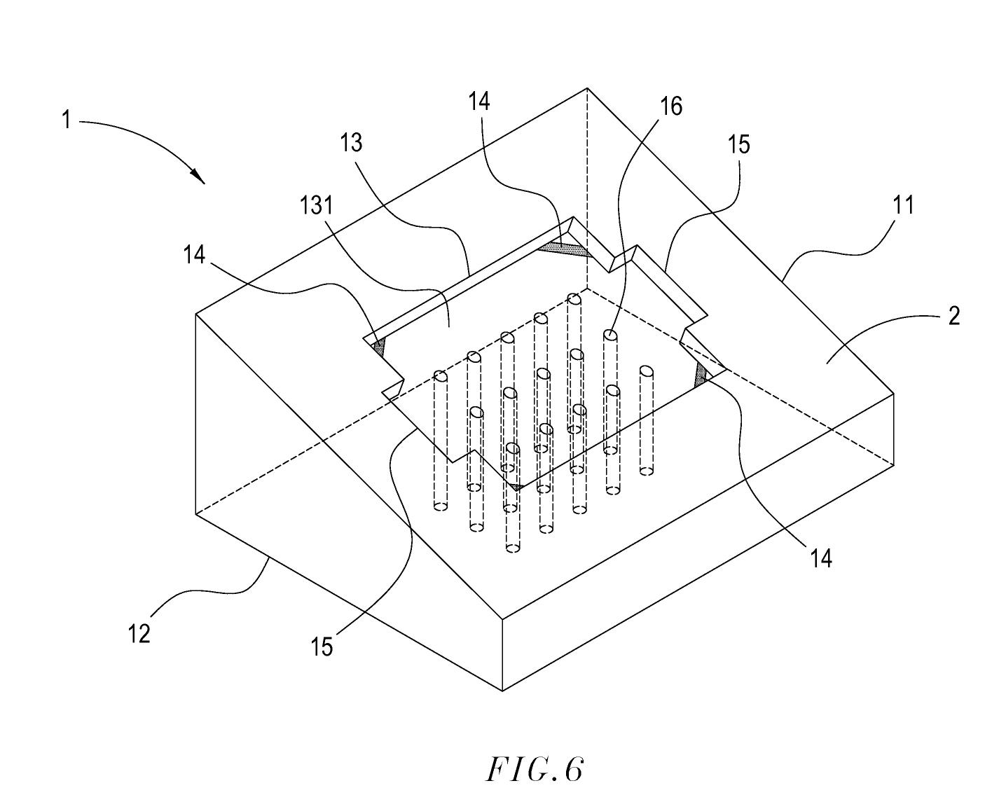

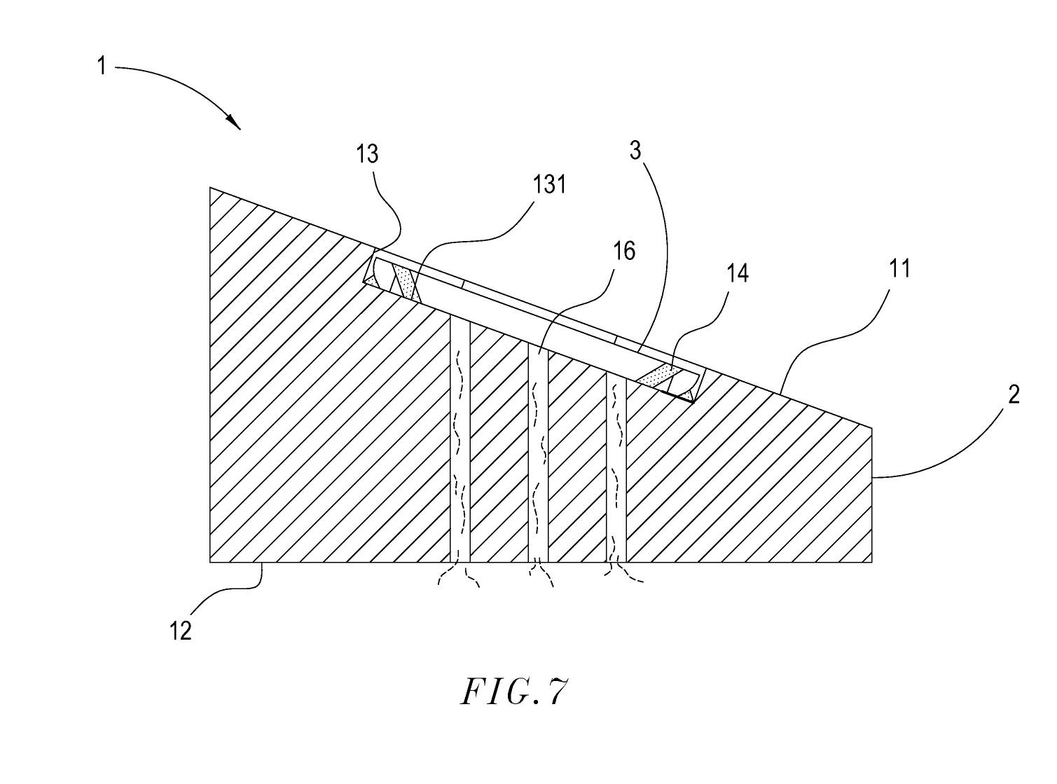

Referring now to FIG. 6 and FIG. 7, a third embodiment of the present invention and its cross-sectional representation are presented. The structure disclosed herein is largely identical to those disclosed in FIG. 1 and FIG. 4. An plurality of inside-outside communicating ventilation channel 16 is formed on the insertion well 131 of the insertion frame 13 of lateral sides thereof. High temperature thermal gas may be discharged accordingly with the structure disclosed thereof upon heat generation from operation of the electronic device 3. Low temperature gas can also convect through the ventilation channels 16 so as to lower the heat generated from operation of the electronic device 3, therefore allowing normal operation of the device 3. Other structures of the invention is identical as those in FIG. 1, or FIG. 4, and further description will be not be provided.

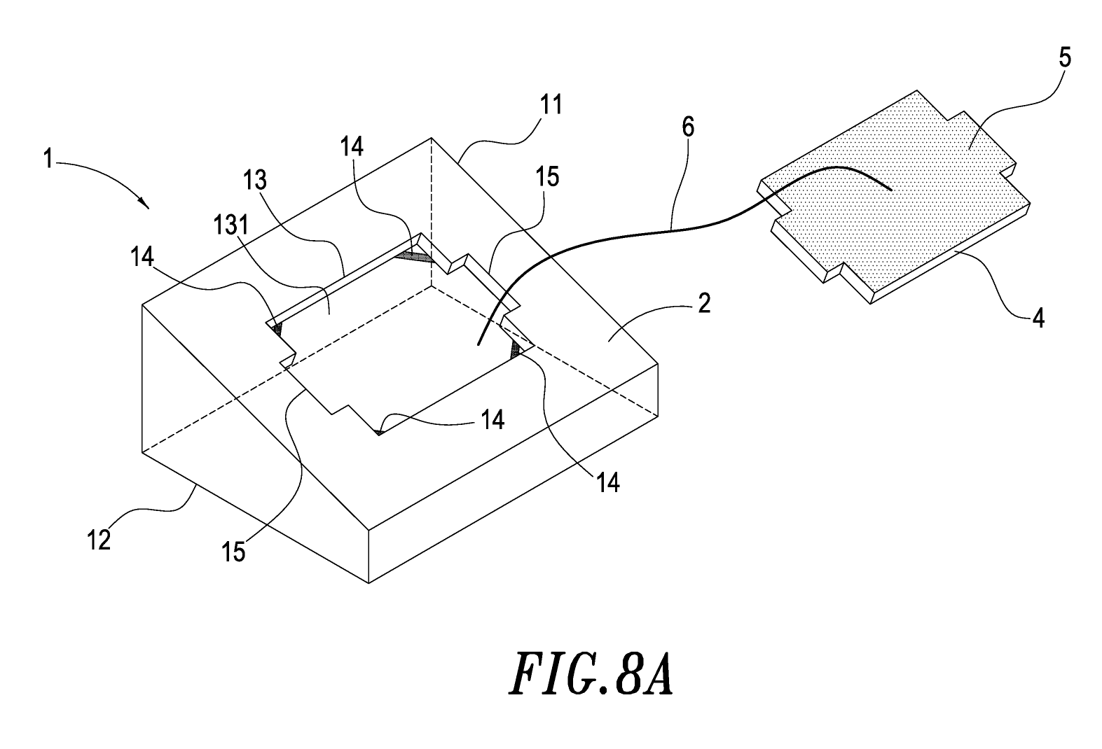

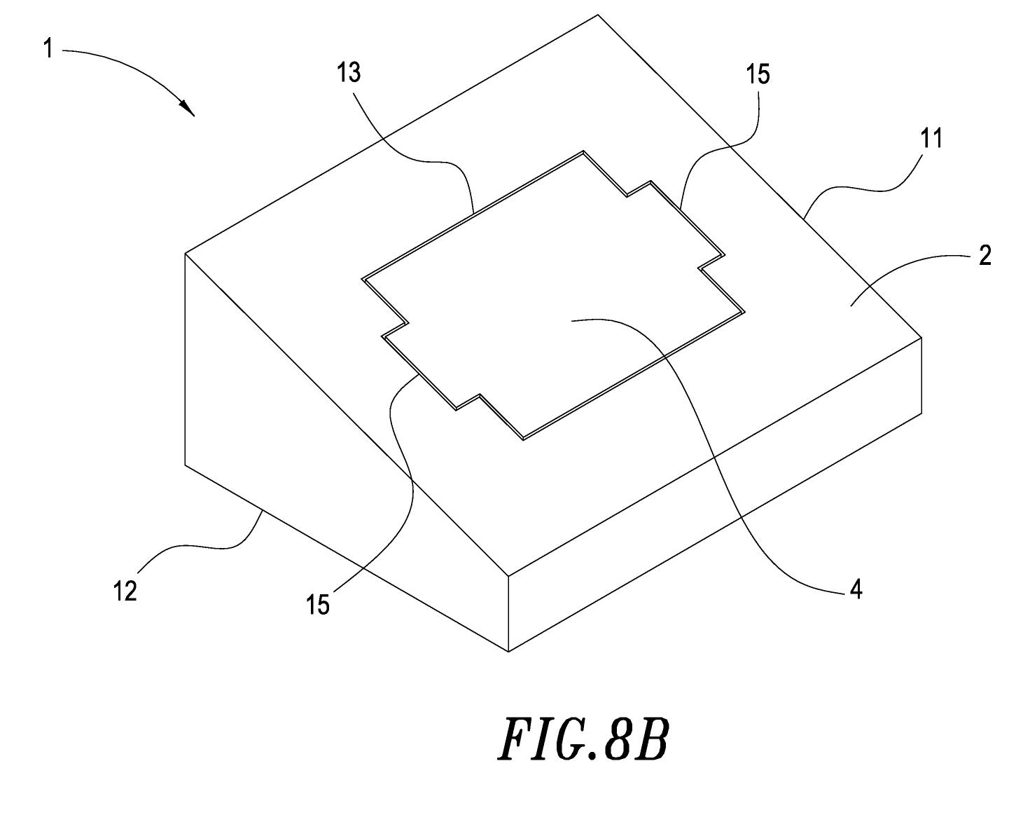

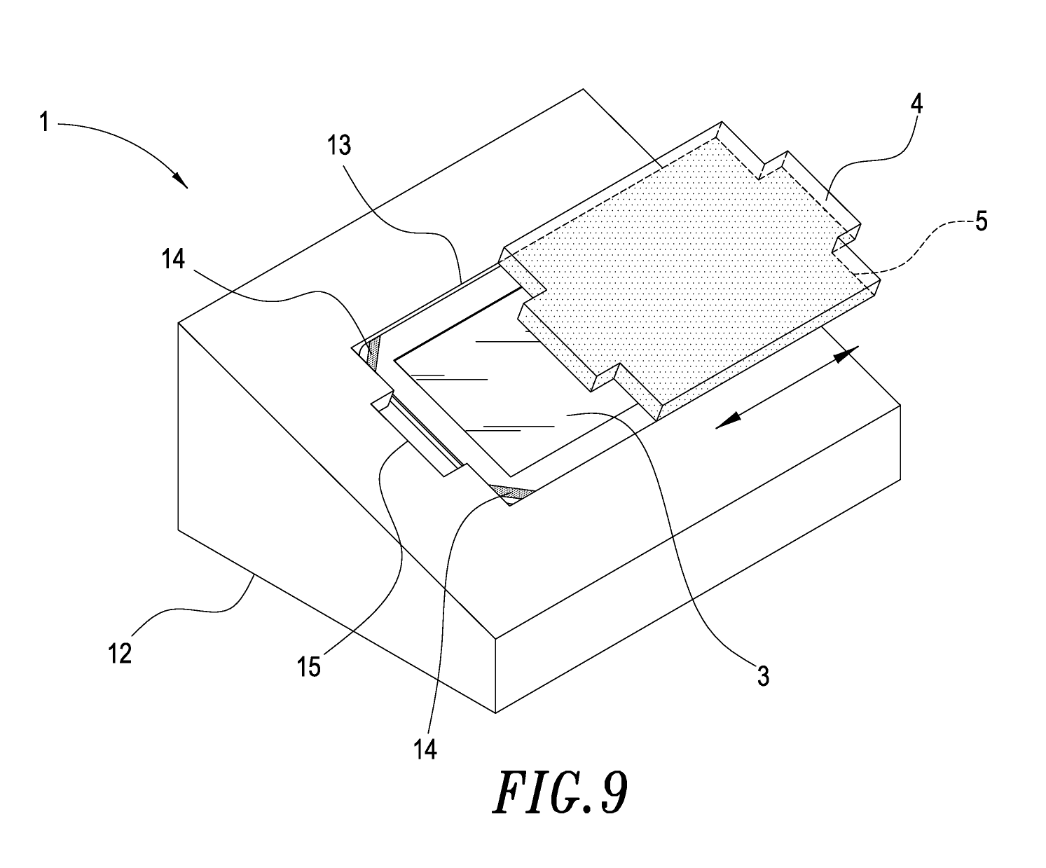

Referring now to FIGS. 8A, 8B and 9, a fourth embodiment of the present invention is disclosed. The difference between the embodiment herein and those as disclosed in FIG. 1, or FIG. 4, or FIG. 7 is the following. A carrier tab 4 is attached to the insertion frame 13 or 13′ of the cushion pad 1 or 1′. The shape of the carrier tab 4 is similar to that of the insertion frame 13, and its exterior dimension is modicumly smaller than that of insertion frame 13, allowing the carrier tab 4 to fill the interior region of the insertion frame 13, thereby benefiting practice of the invention as a cushion pad. Other structures of the invention is identical as those in FIG. 1, or FIG. 4, or FIG. 7, and further description will not be provided.

Additionally, a wiping cloth 5 can be attached to a surface of the carrier tab 4, thereby providing the user a means to wipe the screen of the flat panel electronic device 3 while holding onto the carrier tab 4 so as to clean fingerprints or dust or other impurities on the screen and keep the screen bright and clear.

In another perspective of the present invention, the carrier tab 4 and the insertion frame 13 or 13′ can be connected into one entity with a guiding apparatus 6 or a rope, thereby devoiding the chances of losing the carrier tab 4.

Accordingly, the cushion pad 1 can not only function as a supporting tool against human waist, back, neck, or head, but also a storage means and protective means for flat panel electronic device. When the flat panel electronic device 3 is inserted into the insertion frame 13 of the cushion pad, an optimal viewing angle can be formed. The configuration of the cushion pad 1 of the present invention provides multiple benefits with one presented entity.

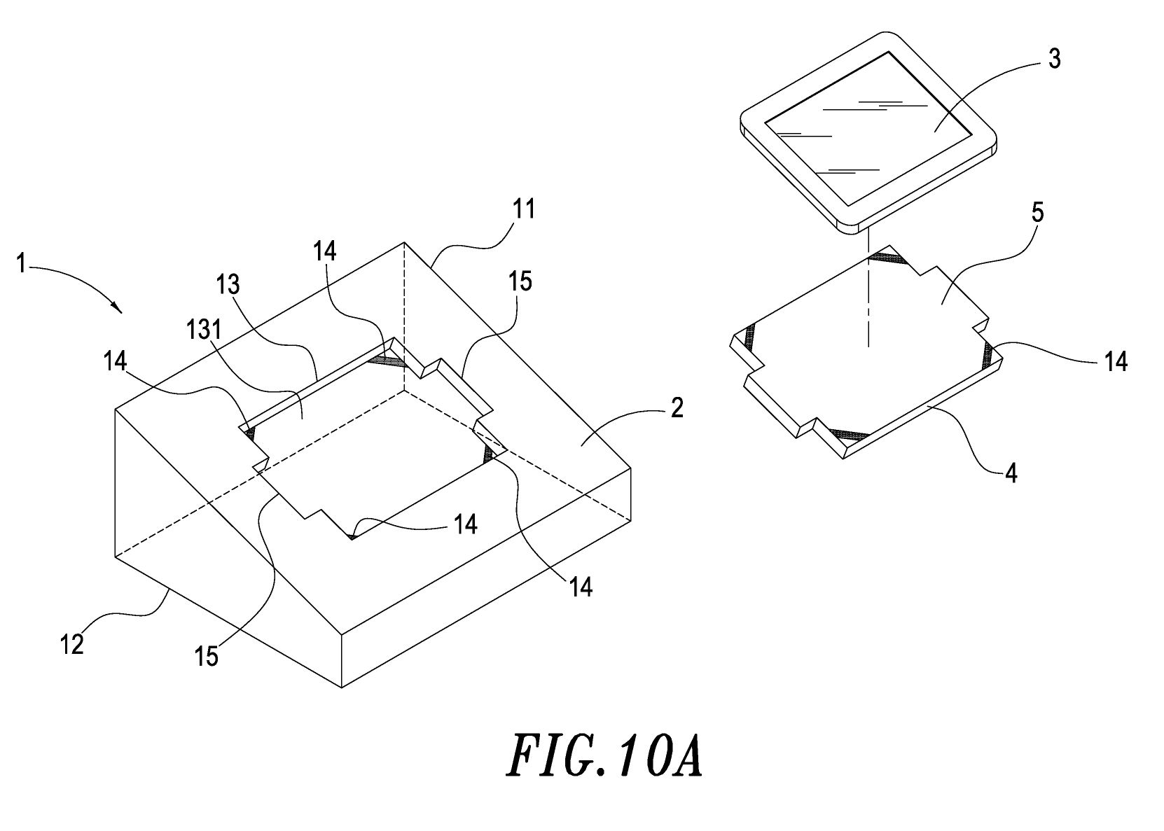

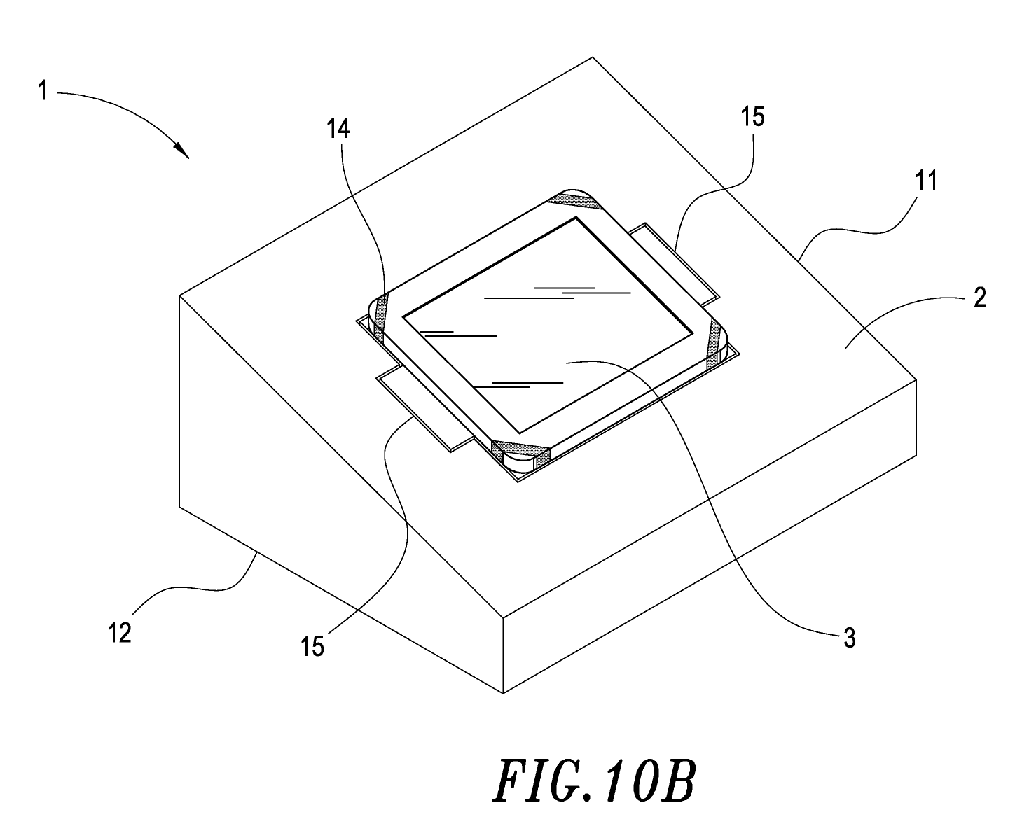

Turning now to FIGS. 10A, 10B, a fifth embodiment of the present invention is presented. The difference between the embodiment herein and those disclosed in FIG. 1, or FIG. 4, or FIG. 7, or FIGS. 8A and 8B, is the following. A fastener 14 can be disposed over the carrier tab 4, thereby providing a means to fix the electronic device 3 in a desired position. When the carrier tab 4 and the insertion frame 13 or 13′ are combined, the user can immediately practice the electronic device inside the cushion pad 1. Other structures of the inveniton is identical as those in FIG. 1, to or FIG. 4, or FIG. 7, or FIGS. 8A and 8B, and further description will not be provided.

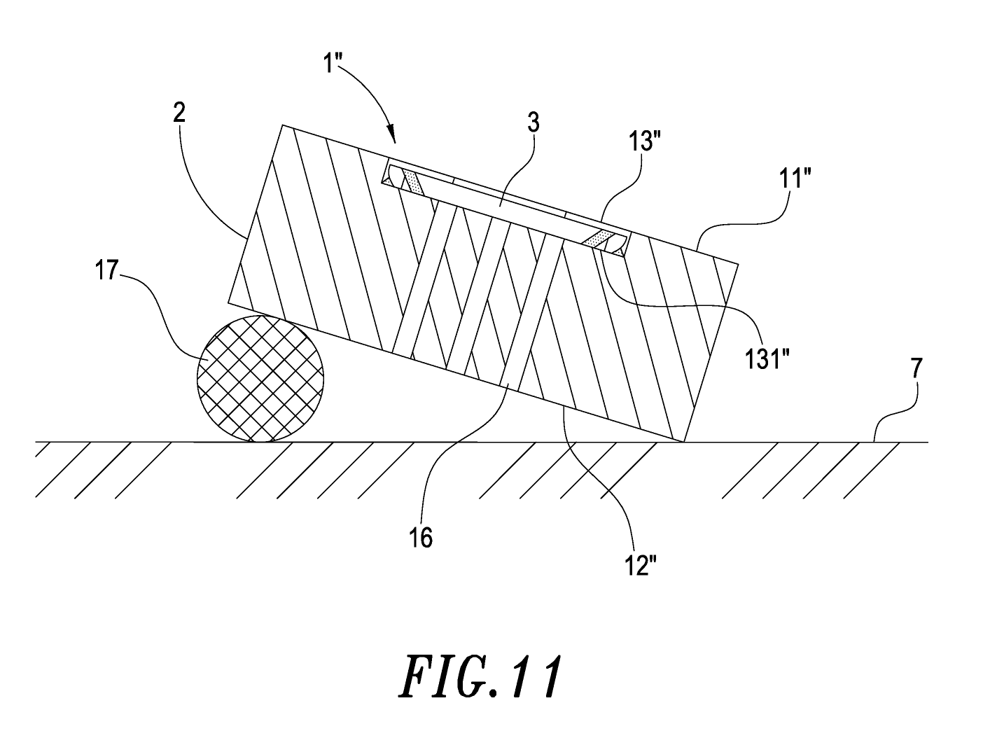

Referring now to FIG. 11, a sixth embodiment of the present invention is presented. Herein, the cushion pad 1″ has at least a receiving surface 11′ and a bottom surface 12″, wherein the receiving surface 11″ and the bottom surface 12″ are corresponding to each other, and an insertion frame 13″ is selectively contoured on said receiving surface 11″, wherein said insertion frame 13″ has an insertion well 131″, and the insertion well 131″ parallels the bottom surface 12″. A plurality of ventilation channels 16 is installed between the bottom surface 12″ and the insertion well 131″ so as to provide a means for discharging heat from the flat panel electronic device 3. A lift apparatus 17 is provided on a side of the bottom surface the cushion pad 1″ to form a height difference so that when the cushion pad 1″ is disposed on the panel surface 7, an angle difference between the insertion well of the cushion 1″ and the panel surface can be formed by adjusting the lift apparatus 17 to tilt the cushion pad 1″, thereby orienting the flat panel electronic device's 3 screen inside the insertion frame 13″ to face the user, and protecting the cushion pad 1″ from damages.

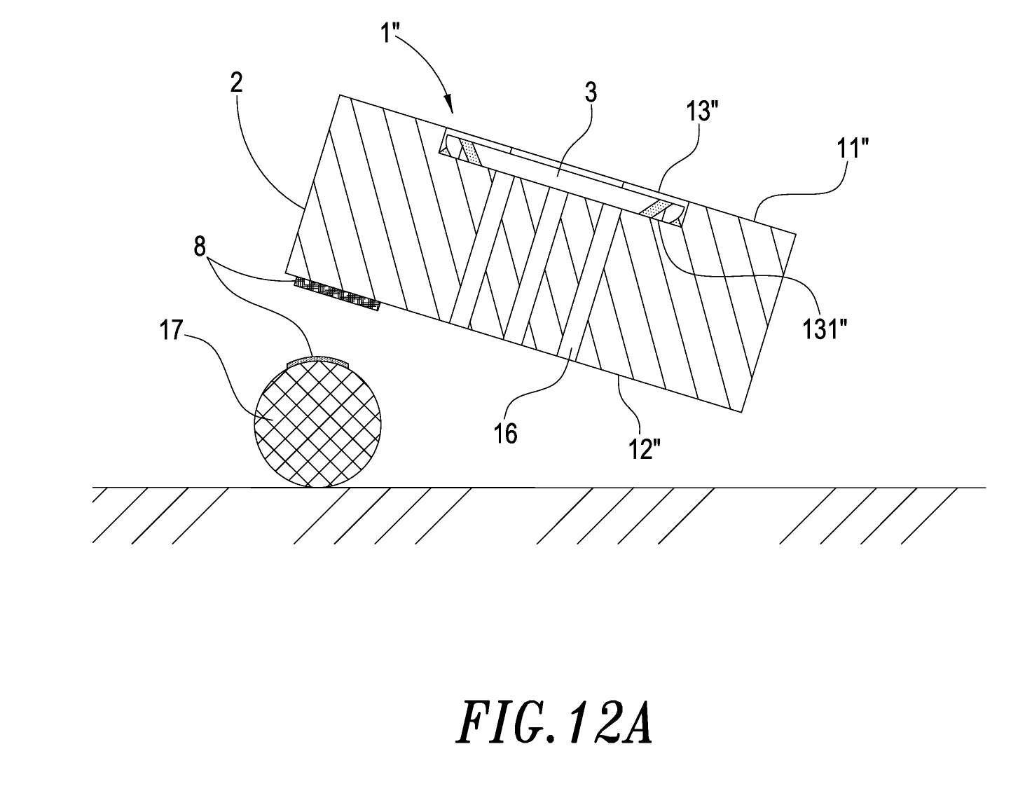

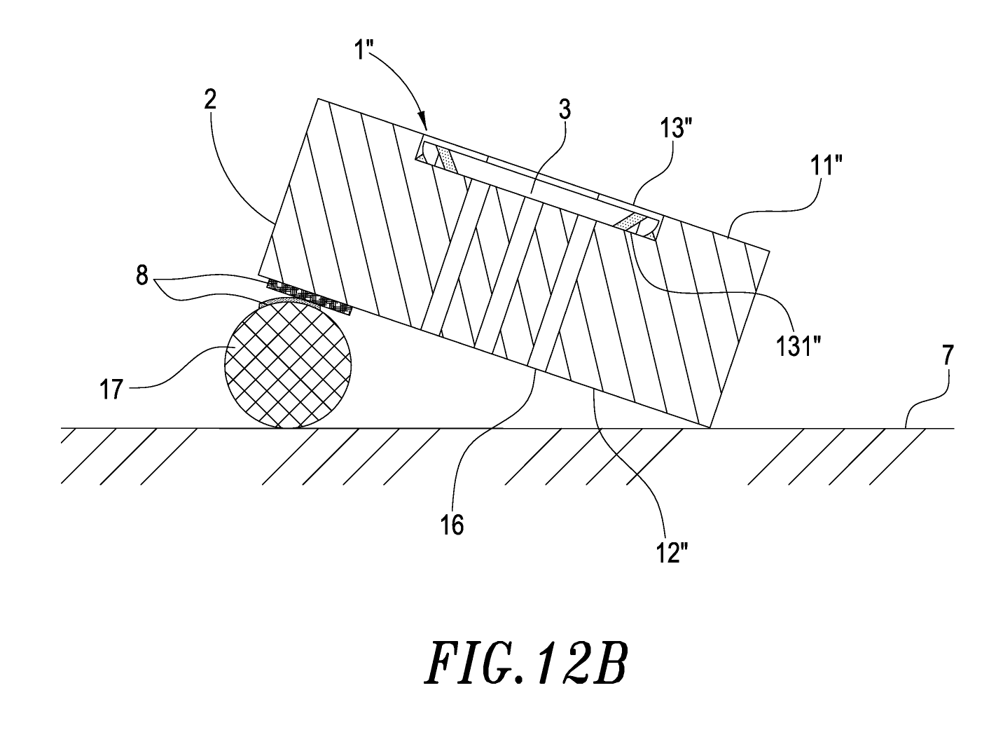

Turning now to FIGS. 12A and 12B, a seventh embodiment of the present invention is disclosed. The difference between the embodiment disclosed herein and that disclosed in FIG. 11 is that lift apparatus 17 and the bottom surface 12″ of the cushion pad 1″ are connected with a connecting means 8, thereby allowing the lift apparatus 17 to be positioned on a side of the bottom surface 12″ of the cushion pad 1″. The connecting means 8 to can be a velcro hook-and-lose stripe or a magnetic type or a zipper type or any combination thereof. The velcro hook-and-lose stripe operates to be disposed on the lift apparatus 17 and the bottom surface 12″, wherein the stripe 81 is a stripe that hooks interchangeably. Other structures of the invention including the cushion pad 1″ are identical as those in FIG. 11, and further description will not be provided.

The cushion pad apparatus for insertion of a flat panel electronic device as disclosed in the present invention, as compared against related conventional arts, offers the following advantages:

1. In the cushion pad apparatus for insertion of a flat panel electronic device of the present invention, the cushion pad has functions both as a regular cushion and a protective means for flat panel electronic device.

2. In the cushion pad apparatus for insertion of a flat panel electronic device of the present invention, when the flat panel electronic device is inserted inside the insertion frame, the flat panel electronic device is subject to the support of the insertion well of the insertion frame, proning the device to an inclined position, thereby benefiting the user to practice the flat panel electronic device.

3. In the cushion pad apparatus for insertion of a flat panel electronic device of the present invention, provision of a fastener ensures the flat panel electronic device for staying in a desired position and no falling out.

What is claimed is:

1. A cushion pad apparatus for insertion of a flat panel electronic device comprising:
a cushion pad having at least a receiving surface and a bottom surface; and
an insertion frame selectively contoured on said receiving surface, wherein said insertion frame has an insertion well, and said insertion frame is disposed at a prescribed angle from said bottom surface.

2. The cushion pad apparatus according to claim 1 further comprising an exterior jacket covering an exterior surface of said cushion pad.

3. The cushion pad apparatus according to claim 1 further comprising a fastener disposed over a portion of said insertion is frame.

4. The cushion pad apparatus according to claim 3 wherein said fastener is a velcro hook-and-loose strap.

5. The cushion pad apparatus according to claim 3 wherein said fastener is a guiding apparatus.

6. The cushion pad apparatus according to claim 1 wherein said cushion pad comprises a material selected from a porous material and silica gel.

7. The cushion pad apparatus according to claim 1 wherein the prescribed angle is between at about 0 degree through 90 degrees.

8. The cushion pad apparatus according to claim 1 wherein a lift apparatus is attached to a side of the bottom surface of the cushion pad.

9. The cushion pad apparatus according to claim 1 wherein a lift apparatus is attached through a connecting means to a side of the bottom surface of the cushion pad.

10. The cushion pad apparatus according to claim 1 further comprising a plurality of ventilation channels disposed through the insertion well of the insertion frame and the bottom surface of the cushion pad.

11. The cushion pad apparatus according to claim 1 further comprising at least a placer for installation of the flat panel electronic device.

12. A cushion pad apparatus for insertion of a flat panel electronic is device comprising:
a cushion pad having at least a receiving surface and a bottom surface;
an insertion frame selectively contoured on said receiving surface, wherein said insertion frame has an insertion well, and said insertion frame is disposed at a prescribed angle from said bottom surface; and
a plurality of ventilation channels disposed through the insertion well and a side thereof.

13. The cushion pad apparatus according to claim 12 wherein a lift apparatus is attached to a side of the bottom surface of the cushion pad.

14. The cushion pad apparatus according to claim 12 wherein a lift apparatus is attached through a connecting means to a side of the bottom surface of the cushion pad.

15. A cushion pad apparatus for insertion of a flat panel electronic device comprising:
a cushion pad having at least a receiving surface and a bottom surface;
an insertion frame selectively contoured on said receiving surface, wherein said insertion frame has an insertion well, and said insertion frame is disposed at a prescribed angle from said bottom surface; and
an exterior jacket having a shape of the insertion frame, the volume thereof smaller than the insertion frame, and said is exterior jacket is substantially attached to the insertion frame.

16. The cushion pad apparatus according to claim 15 wherein the exterior jacket further comprises a cleaning cloth.

17. The cushion pad apparatus according to claim 15 wherein the exterior jacket and the insertion frame are connected with a material selected from a guiding apparatus and a rope.

18. The cushion pad apparatus according to claim 15 further comprising a fastener disposed over a portion of said insertion frame.
